(19) United States
(12) Patent Application Publication
(10) Pub. No.: US 2025/0034430 A1
(43) Pub. Date: Jan. 30, 2025

(54) METHOD FOR PREPARING ORGANIC-INORGANIC NANOCOMPOSITE PARTICLE DISPERSION LIQUID, ORGANIC-INORGANIC NANOCOMPOSITE PARTICLE DISPERSION LIQUID, AND CHEMICAL MECHANICAL POLISHING SOLUTION

(71) Applicant: ANJI MICROELECTRONICS (SHANGHAI) CO.,LTD, Shanghai (CN)

(72) Inventors: Xingping WANG, Shanghai (CN); Pengyu Xu, Shanghai (CN); Changzheng JIA, Shanghai (CN); Fengru LIU, Shanghai (CN); Shoutian LI, Shanghai (CN); Zhan CHEN, Shanghai (CN)

(21) Appl. No.: 18/713,122

(22) PCT Filed: Nov. 30, 2022
(86) PCT No.: PCT/CN2022/135383

§ 371 Date: May 23, 2024

(30) Foreign Application Priority Data
Nov. 30, 2021 (CN) 202111450137.3

(51) Int. Cl. C09G 1/02; C09K 3/14

(52) U.S. Cl. CPC C09G 1/02; C09K 3/1436

(57) ABSTRACT

The present disclosure provides a method for preparing an organic-inorganic nanocomposite particle dispersion, comprising: preparing a negatively charged organic-inorganic nanocomposite particle dispersion: adding positively charged inorganic nanoparticles to an anionic organic polymer solution, stirring thoroughly, dispersing uniformly, and obtaining a negatively charged organic-inorganic nanocomposite particle dispersion; preparing a positively charged organic-inorganic nanocomposite particle dispersion: adding a negatively charged organic polymer inorganic metal oxide composite dispersion to a cationic organic polymer solution, stirring thoroughly, and dispersing uniformly to obtain a positively charged organic polymer inorganic nanocomposite particle dispersion; repeating step (1) and (2) alternately to obtain a dispersion of negatively charged and positively charged organic-inorganic nanocomposites by adjusting the number of step (1) and (2), respectively. Through the above methods, effective control of CMP polishing fluid performance can be achieved.

### TECHNICAL FIELD

The present disclosure relates to a method for preparing an organic-inorganic nanocomposite particle dispersion and a chemical mechanical polishing solution comprising the composite particle dispersion.

### BACKGROUND

With the continuous high-density and miniaturization of semiconductor components, the Chemical Mechanical Planarization (CMP) process plays an indispensable role in the manufacturing process of semiconductor components. In CMP technology, the requirements for chemical mechanical polishing speed, surface flatness, scratches, and the degree of defects are increasing. The CMP polishing fluid has a particularly significant impact on these polishing properties, and polishing particles are the core components of the polishing fluid. By surface engineering modification of polishing particles, the performance of the polishing solution can be adjusted and controlled, and CMP polishing solutions with different characteristics and functions can be developed.

### SUMMARY

A method for preparing an organic-inorganic nanocomposite particle dispersion, comprising:
(1) Preparing for a negatively charged organic-inorganic nanocomposite particle dispersion: adding anionic organic polymers to the positively charged inorganic nanocomposite particle dispersion, stirring thoroughly, and dispersing uniformly to obtain a negatively charged organic polymer inorganic nanocomposite particle dispersion;
(2) Preparing for a dispersion of positively charged organic-inorganic nanocomposite particles: adding cationic organic polymers to the dispersion of negatively charged organic polymer inorganic metal oxide composites, stirring thoroughly, and dispersing uniformly to obtain a dispersion of positively charged organic polymer inorganic nanocomposite particles;
(3) Repeating steps (1) and (2) alternately to obtain a dispersion of negatively charged and positively charged organic-inorganic nanocomposites by adjusting the number of steps (1) and (2), respectively.

Preferably, step (1) occurs at least once or more, and step (2) occurs at least once or more.

A preferred method as claimed in claim 1, wherein the dispersion method comprises one or more of ultrasonic dispersion treatment, high-speed shear treatment, and ball milling treatment; Preferably, during dispersion, adjust the solution pH to 2-8.

Preferably, the inorganic nanoparticles are selected from cerium oxide, cerium hydroxide, and their mixtures.

Preferably, the anionic organic polymer has one or more of —COOH group, —COOR1 group, —SO3H group, —SO3R2 group, —PO3H group, or —PO3R2 group;

Preferably, the anionic organic polymer compound with —COOH group and —COOR1 group is selected from polyacrylic acid and its salts, polymethyl methacrylate and its salts, acrylic acid and methacrylic acid copolymers and their salts, acrylic acid and maleic acid copolymers and their salts, polyaspartic acid and its salts, acrylic acid and styrene copolymers and their salts; The anionic organic polymer compound with —SO3H group and —SO3R2 group is selected from a homopolymer of styrene sulfonic acid or its copolymer, as well as a copolymer of methyl propane sulfonic acid and acrylamide.

Preferably, the weight average molecular weight of the anionic organic polymer ranges from 1000 to 1000000.

The preferred ratio of the mass percentage of anionic organic polymers to inorganic nanoparticles in step (1) is 0.0001-1.

Preferably, in step (2), the cationic organic polymer is selected from one or more of allylamine polymer, diallylamine polymer, vinylamine polymer, and ethylene imine polymer.

Preferably, the weight average molecular weight of the cationic organic polymer ranges from 1000 to 1000000.

The preferred ratio of the mass percentage of cationic organic polymers to inorganic nanoparticles in step (2) is 0.0001-1.

Preferably, taking step (1) as the final step can obtain a negatively charged organic-inorganic nanocomposite particle dispersion, with an electromotive force range of −60 mV to 0 mV for the resulting composite particle dispersion.

Preferably, taking step (2) as the final step can obtain a positively charged organic-inorganic nanocomposite particle dispersion, with an electromotive force range of 0 mV to +60 mV for the resulting composite particle dispersion.

Another aspect of the present disclosure is to provide a chemical mechanical polishing solution comprising an organic inorganic nanocomposite particle dispersion obtained by any of the aforementioned methods.

The preparation method in the present disclosure achieves a significant improvement in the polishing rate of silicon oxide through two-step encapsulation. The surface of cerium oxide particles is positively charged by adding anionic polymers to make their surface negatively charged, and then adding cationic polymers to make their surface positively charged, achieving the following technical effects:
(1) Capable of coating an organic layer on the surface of inorganic nanoparticles through organic-inorganic nanocomposite technology, and effectively controlling the performance of CMP polishing solution by changing the arrangement and composition of organic components;
(2) Organic inorganic nanocomposite particles are composed of relatively hard inorganic cores and relatively soft organic shells. The soft organic shell forms an effective buffer layer between the polished surface and the inorganic core, which is beneficial for reducing defects such as scratches;
(3) Polishing abrasives with different surface charge properties can be obtained by adjusting the preparation process of organic-inorganic nanocomposite particles according to the requirements of chemical mechanical polishing fluids.

### BRIEF DESCRIPTION OF THE DRAWINGS

FIG. 1 depicts the electromotive force and pH value curves of ceria particles in Examples 1A and 2A of the present disclosure.

### DETAILED DESCRIPTION

The advantages of the present disclosure are further elaborated by combining specific embodiments and accompanying drawings.

### Embodiment 1A: Preparation of Negatively Charged Organic-Inorganic Nanocomposite Particle Dispersion

Add 1.6 grams of 5 wt % ammonium polyacrylate (molecular weight˜5000) aqueous solution to 598.4 grams of deionized water, stir for 5 minutes, then add 400 grams of 5 wt % cerium oxide (light scattering particle size 185 nm), stir for 30 minutes, and transfer to a 20 kHz ultrasonic tank for ultrasonic dispersion for 60 minutes. Finally, a negatively charged organic-inorganic nanocomposite particle dispersion (ammonium polyacrylate ceria nanocomposite particles) was obtained with a cerium oxide concentration of 2 wt % and ammonium polyacrylate concentration of 0.04 wt %. The pH, particle size, and zeta potential of the organic-inorganic nanocomposite particle dispersion are listed in Table 1.

### Example 1B: Polishing Solution Including Negatively Charged Organic-Inorganic Nanocomposite Particle Dispersion

Add 400 grams of negatively charged organic-inorganic nanocomposite particle dispersion from Example 1A to 1600 grams of deionized water, adjust the pH to 5.6 with nitric acid, and obtain a CMP polishing solution with a cerium oxide concentration of 0.4 wt %.

### Embodiment 2A: Preparation of Positively Charged Organic-Inorganic Nanocomposite Particle Dispersion

Step 1: Repeat the steps in Example 1A to obtain a dispersion of negatively charged organic-inorganic nanocomposite particles.

Step 2: Prepare a dispersion of positively charged organic-inorganic nanocomposite particles:

Add 18.75 grams of 2 wt % Polyquaternium-37 to 230.7 grams of deionized water, 0.5 grams of 5 wt % nitric acid, stir for 5 minutes, then add 750 grams of negatively charged organic-inorganic nanocomposite dispersion from step one, stir for 30 minutes, and transfer to a 20 kHz ultrasonic tank for ultrasonic dispersion for 120 minutes. Finally, a positively charged organic-inorganic nanocomposite particle dispersion Polyquaternium-37-ammonium polyacrylate-ceria nanocomposite particles) was obtained with a cerium oxide concentration of 1.5 wt %, ammonium polyacrylate concentration of 0.006 wt %, and Polyquaternium-37 concentration of 0.0375 wt %. The pH, particle size, and zeta potential of the organic-inorganic nanocomposite particle dispersion are listed in Table 1.

### Embodiment 2B: Polishing Solution Including Positively Charged Organic-Inorganic Nanocomposite Particle Dispersion

Add 100 grams of positively charged organic-inorganic nanocomposite particle dispersion from Example 2A to 1400 grams of deionized water, adjust the solution pH to 4.8 with nitric acid, and obtain a CMP polishing solution with a cerium oxide concentration of 0.1 wt %.

### Embodiment 3A: Preparation of Negatively Charged Organic-Inorganic Nanocomposite Particle Dispersion

Step 1: Repeat the steps in Example 1A to prepare a dispersion of negatively charged organic-inorganic nanocomposite particles.

Step 2: Repeat the steps in Example 2A to prepare a dispersion of positively charged organic-inorganic nanocomposite particles.

Step 3: Prepare a dispersion of negatively charged organic-inorganic nanocomposite particles Add 4.8 g of 5 wt % ammonium polyacrylate (molecular weight˜5000) to 618.9 g of deionized water, stir for 5 minutes, then add 533.3 g of the positively charged organic-inorganic nanocomposite dispersion prepared in step 2, stir for 30 minutes, and transfer to a 20 kHz ultrasonic tank for ultrasonic dispersion for 120 minutes. Finally, a negatively charged organic-inorganic nanocomposite dispersion (ammonium polyacrylate-Polyquaternium-37-ammonium polyacrylate-cerium oxide nanocomposite particles) was obtained with a cerium oxide concentration of 0.8 wt % and ammonium polyacrylate concentration of 0.024 wt %. The pH, particle size, and zeta potential of the organic-inorganic nanocomposite particle dispersion are listed in Table 1.

### Embodiment 3B: Polishing Solution Including Negatively Charged Organic-Inorganic Nanocomposite Particle Dispersion

Add 400 g of the third organic-inorganic nanocomposite particle dispersion from Example 3A to 1200 g of deionized water, adjust the solution pH to 4.8 with nitric acid, and obtain a CMP polishing solution with a cerium oxide concentration of 0.2 wt %.

### Embodiment 4A: Dispersion of Positively Charged Organic-Inorganic Nanocomposite Particles

Step 1: Repeat the steps in Example 1A to prepare a dispersion of negatively charged organic-inorganic nanocomposite particles.

Step 2: Repeat the steps in Example 2A to prepare a dispersion of positively charged organic-inorganic nanocomposite particles.

Step 3: Repeat the steps in Example 3A to prepare a dispersion of negatively charged organic-inorganic nanocomposite particles.

Step 4: Prepare a dispersion of positively charged organic-inorganic nanocomposite particles. Add 1 gram of 2 wt % Polyquaternium-37 to 749.0 grams of deionized water, stir for 5 minutes, then add 250 grams of negatively charged organic-inorganic nanocomposite dispersion prepared in step three, stir for 30 minutes, transfer to a 20 kHz ultrasonic tank, and disperse for 120 minutes. Finally, a positively charged organic-inorganic nanocomposite particle dispersion (Polyquaternium-37-ammonium polyacrylate-Polyquaternium-37-ammonium polyacrylate-cerium oxide nanocomposite particles) was obtained with a cerium oxide concentration of 0.2 wt % and a Polyquaternium-37 concentration of 0.002 wt %. The pH, particle size, and zeta potential of the organic-inorganic nanocomposite particle dispersion are listed in Table 1.

### Comparative Embodiment 1

Add 80 grams of 5 wt % ceria to 1920 grams of deionized water, stir for 5 minutes, adjust the pH to 4.8 by adding nitric acid, and finally obtain a CMP polishing solution with a ceria concentration of 0.2%.

### Comparative Embodiment 2

Add 1 g of 10 wt % Polyquaternium-37 to deionized water, stir well, then add 80 g of 5 wt % ceria to the above solution, adjust the pH to 4.8 with nitric acid, and finally obtain a CMP polishing solution with a ceria concentration of 0.2%.

Test the surface potential and particle size of ceria particles in the above embodiments, the pH value of the dispersion, and observe the stability of the corresponding ceria particles. The measurement results and stability observation results are recorded in Table 1.

TABLE 1
Measurement results of surface potential, particle size, and
stability of organic-inorganic nanocomposite particles

| | | Surface | Particle | stability of |
|---|---|---|---|---|
| | pH | Potential (mV) | Size (nm) | particles |
| Embodiment 1A | 7.5 | −24 | 185 | >3 weeks |
| Embodiment 2A | 4.8 | +28 | 210 | >3 weeks |
| Embodiment 3A | 5.6 | −23 | 195 | >3 weeks |
| Embodiment 4A | 4.8 | +17 | 235 | >3 weeks |
| Comparative embodiment 1 | 4.8 | +41 | 185 | >3 weeks |
| Comparative embodiment 2 | 4.8 | +45 | 187 | >3 weeks |

Based on the above measurement results, it can be concluded that the method for preparing the organic-inorganic nanocomposite particles provided in this application can not only achieve stable dispersion of ceria particles, but also change the surface charge properties of ceria composite particles.

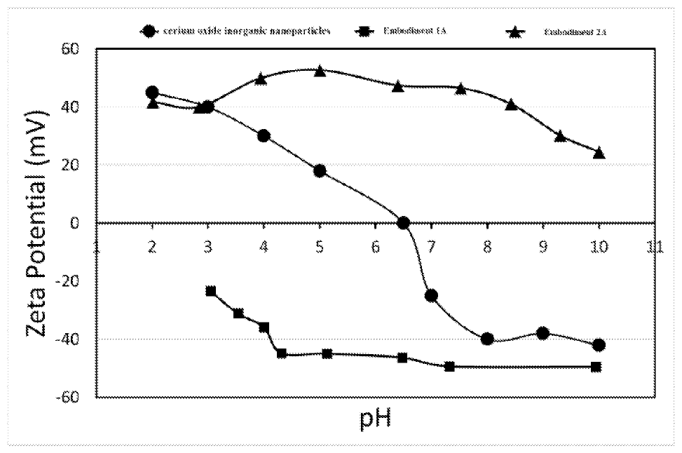

The relationship curve between the electromotive potential and pH of the negatively charged organic-inorganic nanocomposite particle dispersion prepared in Example 1A is shown in FIG. 1. The electromotive potential is always less than −20 mV in the pH 3-10 range, indicating that it has good colloidal stability in the pH 3-10 range. As shown in FIG. 1, the electrokinetic potential of the negatively charged organic-inorganic nanocomposite particle dispersion prepared in Example 2A is always greater than 20 mV, indicating that it has good colloidal stability in the pH range of 2-10. This characteristic enables the organic-inorganic nanocomposite particles in the present disclosure to adapt to a wider pH range, greatly expanding their application in chemical mechanical polishing fluids.

In order to further illustrate the polishing performance of the organic-inorganic nanocomposite particles prepared by the present disclosure, and to further test the polishing rate of the organic-inorganic nanocomposite particle dispersion on silicon oxide in the above embodiments. The specific testing conditions are as follows:

Use CMP grinding equipment (manufactured by Applied materials company, trade name: Mira) for grinding. The grinding pad uses an IC1000 polishing pad manufactured by 3M company, with a grinding pressure of 2.0 psi. The rotation of the grinding disc and grinding seat are 93 rpm and 87 rpm, respectively, and the polishing fluid flow rate is 150 mL/min.

A 200 mm PE-TEOS silicon oxide film was used as the semiconductor substrate, and the difference in TEOS film thickness was measured using the NanoSpec film thickness measurement system (NanoSpec6100-300, Shanghai Nanospec Technology Corporation). Starting from the 3 mm edge of the wafer, measure 49 points on the diameter line at equal intervals. The polishing rate is the average of 49 points. The specific test results are shown in Table 2.

TABLE 2
Polishing Rate of Disperse Liquid in Embodiments and Comparative embodiments

| | | | | | | Comparative | Comparative |
|---|---|---|---|---|---|---|---|
| | | Embodiment 1B | Embodiment 2B | Embodiment 3B | Embodiment 4A | embodiment 1 | embodiment 2 |
| Grinding particle content (wt %) | | 0.4 | 0.1 | 0.2 | 0.2 | 0.2 | 0.2 |
| Anionic | material | Ammonium | Ammonium | Ammonium | Ammonium | — | — |
| organic | | polyacrylate | polyacrylate | polyacrylate | polyacrylate | | |
| polymers | Content | 0.0068 | 0.0008 | 0.0068 | 0.0016 | — | — |
| Cationic | material | — | Polyquaternium- | Polyquaternium- | Polyquaternium- | — | Polyquaternium- |
| organic | | | 37 | 37 | 37 | | 37 |
| polymers | Content | — | 0.005 | 0.005 | 0.005 | — | 0.005 |

| | | | | | | |
|---|---|---|---|---|---|---|
| pH | 5.6 | 4.8 | 5.6 | 4.8 | 4.8 | 4.8 |
| Polishing Rate (Å/min) | 1386 | 3691 | 489 | 2512 | 2570 | 2974 |

Based on the above test results, it can be seen that the polishing solution in Example 2B and Example 4A has excellent polishing rate. Examples 2B and 4A contain positively charged inorganic nano ceria composite particles in the dispersion, which exhibit good polishing performance. The surface of the ceria particles in Examples 1B and 3B is covered with negative charges, which is not conducive to polishing, but is beneficial for continuing to cover the surface with positive charges to change the surface properties of the nanocomposite particles.

The preparation method in the present disclosure can coat an organic layer on the surface of inorganic nanoparticles through organic-inorganic nanocomposite technology, and effectively regulate the performance of CMP polishing solution by changing the arrangement and composition of organic components; Organic inorganic nanocomposite particles are composed of relatively hard inorganic cores and relatively soft organic shells. The soft organic shell forms an effective buffer layer between the polished surface and the inorganic core, which is beneficial for reducing defects such as scratches; Polishing abrasives with different surface charge properties can be obtained by adjusting the preparation process of organic-inorganic nanocomposite particles according to the requirements of chemical mechanical polishing fluids.

All content percentages in this disclosure are mass percentage contents.

It should be noted that the embodiments of the present disclosure have better implement ability and do not impose any form of limitation on the present disclosure. Any skilled person familiar with the art may use the disclosed technical content to modify or modify them into equivalent effective embodiments. However, any modifications or equivalent changes and modifications made to the above embodiments based on the technical essence of the present disclosure without departing from the content of the disclosed technical solution still fall within the technical scope of the present disclosure.

1. A method for preparing an organic-inorganic nanocomposite particle dispersion, comprising:
(1) preparing a dispersion of negatively charged organic-inorganic nanocomposite particles comprising adding positively charged inorganic nanoparticles to an anionic organic polymer solution, stirring thoroughly, and dispersing uniformly to obtain a dispersion of negatively charged organic-inorganic nanocomposite particles;
(2) preparing a positively charged organic-inorganic nanocomposite particle dispersion comprising adding a negatively charged organic polymer inorganic metal oxide composite dispersion to a cationic organic polymer solution, stirring thoroughly, and dispersing uniformly to obtain a positively charged organic polymer inorganic nanocomposite particle dispersion;
(3) repeating steps (1) and (2) alternately to obtain a dispersion of negatively charged and positively charged organic-inorganic nanocomposites by adjusting the number of steps (1) and (2), respectively.

2. The method as claimed in claim 1, wherein the step (1) occurs at least once or more, and the step (2) occurs at least once or more.

3. The method as claimed in claim 1, wherein the dispersion method comprises one or more of ultrasonic dispersion treatment, high-speed shear treatment, and ball milling treatment.

4. The method as claimed in claim 1, wherein the inorganic nanoparticles are selected from cerium oxide, cerium hydroxide, and their mixtures.

5. The method as claimed in claim 1, wherein the anionic organic polymer has one or more of —COOH group, —COOR1 group, —SO₃H group, and —SO₃R2, —PO₃H group, and —PO₃R2 group.

6. The method as claimed in claim 1, wherein the anionic organic polymer has a weight average molecular weight ranging from 1000 to 1000000.

7. The method as claimed in claim 1, wherein a mass percentage ratio of the anionic organic polymer to the inorganic nanoparticles in the step (1) is 0.0001-1.

8. The method as claimed in claim 1, wherein in step (2), the cationic organic polymer is one or more selected from allylamine polymer, diallylamine polymer, vinylamine polymer, and vinylamine polymer.

9. The method as claimed in claim 1, wherein the cationic organic polymer has a weight average molecular weight ranging from 1,000 to 1,000,000.

10. The method as claimed in claim 1, wherein a mass percentage ratio of cationic organic polymer to inorganic nanoparticles in the step (2) is 0.0001-1.

11. The method as claimed in claim 1, wherein the step (1) serves as the final step to obtain a negatively charged organic-inorganic nanocomposite particle dispersion, with an electromotive force range of −60 mV to 0 mV for the resulting composite particle dispersion.

12. The method as claimed in claim 1, wherein the step (2) serves as the final step to obtain a positively charged organic-inorganic nanocomposite particle dispersion, with an electromotive force range of 0 mV to +60 mV for the resulting composite particle dispersion.

13. An organic-inorganic nanocomposite particle dispersion obtained by the method of claim 1.

14. A chemical mechanical polishing solution comprising an organic-inorganic nanocomposite particle dispersion as claimed in claim 13.
